(19) United States
(12) Patent Application Publication
(10) Pub. No.: US 2021/0072273 A1
(43) Pub. Date: Mar. 11, 2021

(54) FAN CIRCUIT TEST SYSTEM AND TEST METHOD WITHOUT THE NEED TO INSTALL A FAN

(71) Applicants: Inventec (Pudong) Technology Corp., Shanghai (CN); Inventec Corporation, Taipei (TW)

(72) Inventor: Chih-Shien Chien, Taipei (TW)

(21) Appl. No.: 16/572,635

(22) Filed: Sep. 17, 2019

(30) Foreign Application Priority Data
Sep. 6, 2019 (CN) 201910843205.9

(51) Int. Cl. G01P 3/48; H03K 7/08

(52) U.S. Cl. CPC G01P 3/4805; H03K 7/08

(57) ABSTRACT

A controller is used to output a first pulse width modulation signal to a fan connector, and perform a test according to the first pulse width modulation signal and a first fan speed signal so as to determine whether a circuit related to a fan is normal. The fan connector is used to output a second pulse width modulation signal corresponding to the first pulse width modulation signal to the feedback device, and output the first fan speed signal corresponding to a second fan speed signal to the controller. The feedback device is used to generate the second fan speed signal corresponding to the second pulse width modulation signal, and output the second fan speed signal to the fan connector.

### BACKGROUND OF THE INVENTION

### 1. Field of the Invention

The disclosure is related to a fan circuit test system and a test method, and more particularly, a fan circuit test system and a test method without the need to install a fan.

### 2. Description of the Prior Art

In the current production process of a circuit board (such as a motherboard), a hardware circuit test for controlling and detecting a fan speed is to install a fan on the circuit board and set different fan speed control signals to control the fan. After the fan is in operation, a pre-defined test program can be used to test whether the circuit is normal according to actual measurement results of the fan speed.

The disadvantage of the above process includes that the fan must be mounted on the board and the fan must be operated. Since the fan itself is a consumable device, the fan will eventually wear out. In addition, due to the limitations of physical characteristics, when the signal for controlling the fan speed has been set, it takes a while for the fan to reach a desirable speed. Hence, the overall testing process is quite time consuming. In addition, if an abnormal test result occurs during the production process, a tester must further clarify whether the fan or the board is at fault. This imposes more burden to the debugging process. In order to carry out the above process, spare fans must be prepared for replacement during production and testing, introducing additional burden. In addition, there is no proper solution for testing a circuit board that does not have a fan pre-installed or a circuit board whose fan installed thereon does not have its type specified.

### SUMMARY OF THE INVENTION

An embodiment of the disclosure provides a fan circuit test system including a controller, a fan connector and a feedback device. The controller is used to output a first pulse width modulation signal and perform a test according to the first pulse width modulation signal and a first fan speed signal, and includes a pulse width modulation signal terminal configured to output the first pulse width modulation signal; and a fan speed signal terminal configured to receive the first fan speed signal. The fan connector is used to output a second pulse width modulation signal corresponding to the first pulse width modulation signal and output the first fan speed signal corresponding to a second fan speed signal, and includes a first input terminal coupled to the pulse width modulation signal terminal of the controller and used to receive the first pulse width modulation signal; a first output terminal used to output the second pulse width modulation signal; a second input terminal used to receive the second fan speed signal; and a second output terminal coupled to the fan speed signal terminal of the controller and used to output the first fan speed signal. The feedback device is used to generate the second fan speed signal corresponding to the second pulse width modulation signal, and includes a first terminal coupled to the first output terminal of the fan connector and used to receive the second pulse width modulation signal; and a second terminal coupled to the second input terminal of the fan connector and used to output the second fan speed signal.

Another embodiment of the disclosure provides a test method used for a fan circuit test system. The fan circuit test system includes a controller, a fan connector coupled to the controller, and a feedback device coupled to the fan connector. The test method includes the controller outputting a first pulse width modulation signal to the fan connector; the fan connector outputting a second pulse width modulation signal corresponding to the first pulse width modulation signal to the feedback device; the feedback device outputting a second fan speed signal corresponding to the second pulse width modulation signal to the fan connector; the fan connector outputting a first fan speed signal corresponding to the second fan speed signal to the controller; and the controller performing a test according to the first fan speed signal and the first pulse width modulation signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a fan circuit test system according to an embodiment.

FIG. 2 illustrates a test method for the fan circuit test system of FIG. 1 according to an embodiment.

FIG. 3 illustrates a flowchart of using the test method of FIG. 2 to check duty cycles and frequencies of signals according to an embodiment.

### DETAILED DESCRIPTION

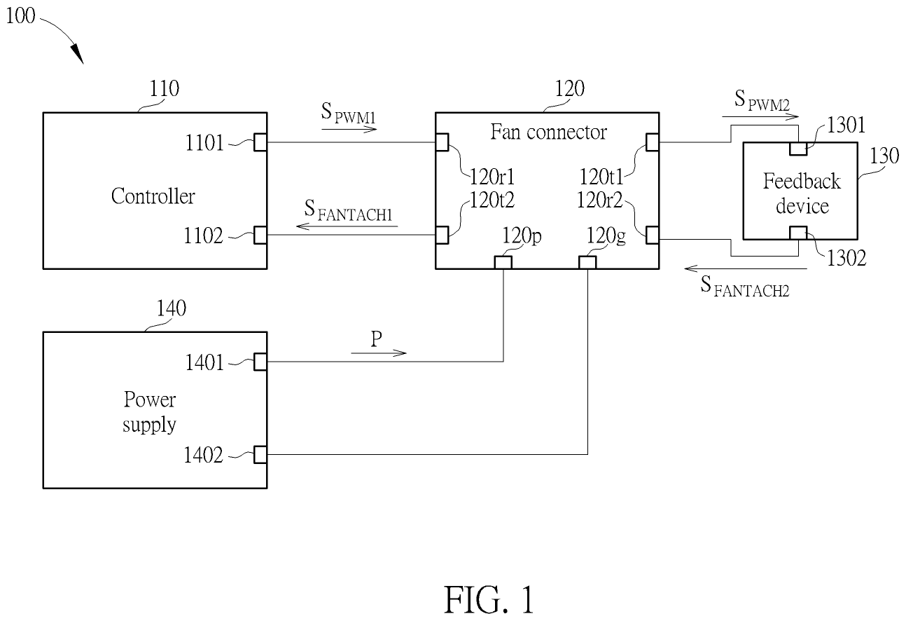

FIG. 1 illustrates a fan circuit test system 100 according to an embodiment. The fan circuit test system 100 may include a controller 110, a fan connector 120 and a feedback device 130. The controller 110 may be used to output a first pulse width modulation signal S_{PWM1} and perform a test according to the first pulse width modulation signal S_{PWM1} and a first fan speed signal S_{FANTACH1} so as to determine whether a circuit related to a fan is normal. The controller 110 may include a pulse width modulation signal terminal 1101 used to output the first pulse width modulation signal S_{PWM1}, and a fan speed signal terminal 1102 used to receive the first fan speed signal S_{FANTACH1}.

The fan connector 120 may be used to output a second pulse width modulation signal S_{PWM2} corresponding to the first pulse width modulation signal S_{PWM1} and output the first fan speed signal S_{FANTACH1} corresponding to a second fan speed signal S_{FANTACH2}. The fan connector 129 may include a first input terminal 120r1 coupled to the pulse width modulation signal terminal 1101 of the controller 110 and used to receive the first pulse width modulation signal S_{PWM1}, a first output terminal 120t1 used to output the second pulse width modulation signal S_{PWM2}, a second input terminal 120r2 used to receive the second fan speed signal S_{FANTAcH2}, and a second output terminal 120t2 coupled to the fan speed signal terminal 1102 of the controller 110 and used to output the first fan speed signal S_{FANTACH1}.

The feedback device 130 may be used to generate the second fan speed signal S_{FANTAcH2} corresponding to the second pulse width modulation signal S_{PWM2}. The feedback device 130 may include a first terminal 1301 coupled to the first output terminal 120t1 of the fan connector 120 and used to receive the second pulse width modulation signal S_{PWM2}, and a second terminal 1302 coupled to the second input terminal 120r2 of the fan connector 120 and used to output the second fan speed signal S_{FANTACH2}.

According to an embodiment, when a circuit of the fan connector 120 operates normally, the first pulse width modulation signal S_{PWM1} may be identical to the second pulse width modulation signal S_{PWM2}, and the first fan speed signal S_{FANTACH1} may be identical to the second fan speed signal S_{FANTACH2}.

According to an embodiment, when a circuit of the feedback device 130 operates normally, the second pulse width modulation signal S_{PWM2} may be identical to the second fan speed signal S_{FANTACH2}.

According to an embodiment, the controller 110 may include a baseboard management controller (BMC). According to an embodiment, the feedback device 130 may include a jumper or a customized connector.

According to an embodiment, as shown in FIG. 1, the fan circuit test system 100 may further include a power supply 140. The power supply 140 may include a first terminal 1401 used to provide power P and a second terminal 1402 coupled to a ground. The fan connector 120 may further include a power terminal 120p coupled to the first terminal 1401 of the power supply 140 and used to receive the power P, and a ground terminal 120g coupled to the second terminal 1402 of the power supply 140.

According to an embodiment, the controller 110, the fan connector 120, the feedback device 130 and the power supply 140 may be installed on a same circuit board such as a motherboard. According to another embodiment, the power supply 140 may be an externally connected device. According to an embodiment, the feedback device 130 may be a pluggable device which may be installed when testing a circuit and removed after the test is finished. The terminals used to install the feedback device 130 may be used for installing a fan afterward.

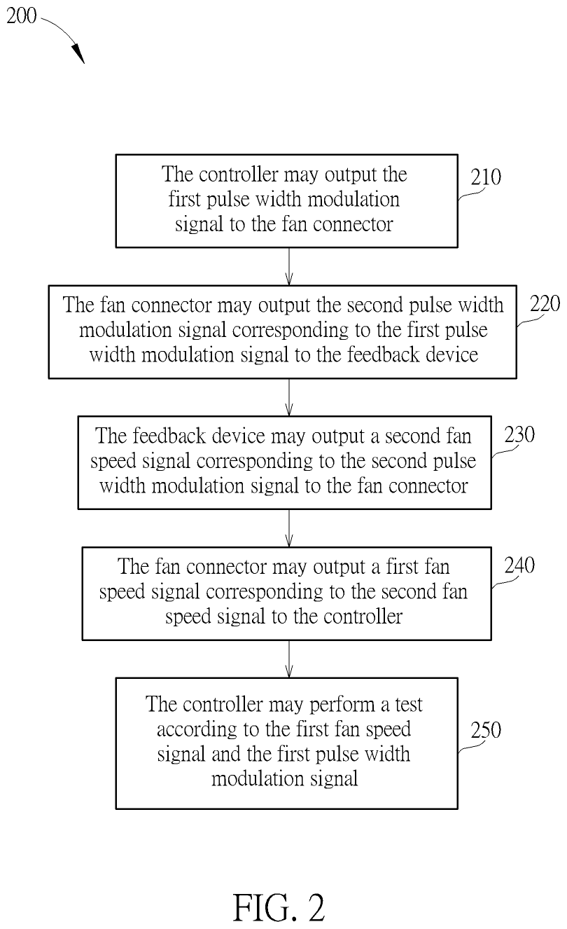

FIG. 2 illustrates a test method 200 for the fan circuit test system 100 of FIG. 1 according to an embodiment. As shown in FIG. 2, the test method 200 may include the following steps.

Step 210: the controller 110 may output the first pulse width modulation signal S_{PWM1} to the fan connector 120;

Step 220: the fan connector 120 may output the second pulse width modulation signal S_{PWM2} corresponding to the first pulse width modulation signal S_{PWM1} to the feedback device 130;

Step 230: the feedback device 130 may output a second fan speed signal S_{FANTACH2} corresponding to the second pulse width modulation signal S_{PWM2} to the fan connector 120;

Step 240: the fan connector 120 may output a first fan speed signal S_{FANTACH1} corresponding to the second fan speed signal S_{FANTACH2} to the controller 110; and

Step 250: the controller 110 may perform a test according to the first fan speed signal S_{FANTACH1} and the first pulse width modulation signal S_{PWM1}.

According to an embodiment, in Step 210, the controller 110 may set the first pulse width modulation signal S_{PWM1} so that the first pulse width modulation signal S_{PWM1} may have a predetermined duty cycle, and a frequency corresponding to a waveform of the first pulse width modulation signal S_{PWM1} may be fixed. In Step 240, the controller 110 may check whether the first fan speed signal S_{FANTACH1} has the predetermined duty cycle. When circuits of the fan connector 120 and the feedback device 130 are normal, the first pulse width modulation signal S_{PWM1}, the second pulse width modulation signal S_{PWM2}, the first fan speed signal S_{FANTACH1} and the second fan speed signal S_{FANTACH2} of FIG. 1 may have an identical duty cycle. Hence, in Step 240, when the first fan speed signal S_{FANTACH1} has the predetermined duty cycle identical to that of the first pulse width modulation signal S_{PWM1}, it may be determined that the circuit related to a fan is normal. On the contrary, when the first fan speed signal S_{FANTACH1} fails to have the predetermined duty cycle identical to that of the first pulse width modulation signal S_{PWM1}, it may be determined that the circuit related to a fan is abnormal, and a debugging process may be performed.

According to an embodiment, in Step 210, the controller 110 may set the first pulse width modulation signal S_{PWM1} so that the first pulse width modulation signal S_{PWM1} may have a predetermined frequency, and a duty cycle corresponding to a waveform of the first pulse width modulation signal S_{PWM1} may be fixed. In Step 240, the controller 110 may check whether the first fan speed signal S_{FANTACH1} has the predetermined frequency. When circuits of the fan connector 120 and the feedback device 130 are normal, the first pulse width modulation signal S_{PWM1}, the second pulse width modulation signal S_{PWM2}, the first fan speed signal S_{FANTACH1} and the second fan speed signal S_{FANTACH2} of FIG. 1 may have an identical frequency. Hence, in Step 240, when the first fan speed signal S_{FANTACH1} has the predetermined frequency identical to that of the first pulse width modulation signal S_{PWM1}, it may be determined that the circuit related to a fan is normal. On the contrary, when the first fan speed signal S_{FANTACH1} fails to have the predetermined frequency identical to that of the first pulse width modulation signal S_{PWM1}, it may be determined that the circuit related to a fan is abnormal, and a debugging process may be performed.

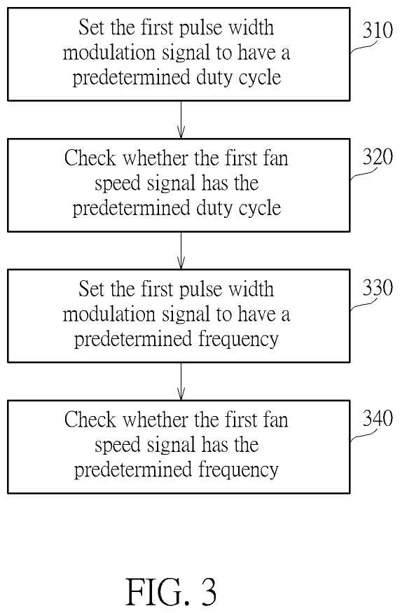

The above checks related to a duty cycle and a frequency may be performed sequentially as shown in FIG. 3. FIG. 3 illustrates a flowchart of using the test method 200 of FIG. 2 to check duty cycles and frequencies of signals according to an embodiment. According to an embodiment, the following steps may be performed.

Step 310: set the first pulse width modulation signal S_{PWM1} to have a predetermined duty cycle;

Step 320: check whether the first fan speed signal S_{FANTACH1} has the predetermined duty cycle;

Step 330: set the first pulse width modulation signal S_{PWM1} to have a predetermined frequency; and

Step 340: check whether the first fan speed signal S_{FANTACH1} has the predetermined frequency.

Step 310 and Step 320 may be performed corresponding to above Step 210 to Step 250 where Step 210 may include Step 310, and Step 250 may include Step 320. Step 330 and Step 340 may be performed corresponding to above Step 210 to Step 250 where Step 210 may include Step 330, and Step 250 may include Step 340. If any check result of Step 320 and Step 340 indicates that the first fan speed signal S_{FANTACH1} does not have the predetermined duty cycle and/or the predetermined frequency, a debugging process may be performed according to the testing process.

For example, the predetermined duty cycle in Step 310 may be set as 50%. That means a ratio of a time interval of a higher level to another time interval of a lower level in a waveform of the signal may be 50%. If the circuit is normal, in Step 320, the duty cycle of the first fan speed signal S_{FANTACH1} may also be 50%. For example, in Step 330, the predetermined frequency may be set as 12.20 hertz, and a period of the signal may be 81920 μsec. If the circuit is normal, in Step 340, the frequency of the first fan speed signal S_{FANTACH1} may also be 12.20 hertz. The abovementioned duty cycle and frequency are merely examples instead of limiting the scope of embodiments. Step 310 to Step 340 may be repeatedly performed for several cycles according to a predetermined testing process. In different tests, different duty cycles and frequencies may be used to cover more testing ranges.

Step 310 and Step 320 are related to one another, and Step 330 and Step 340 are related to one another. According to an embodiment, Step 310 and Step 320 may be performed before performing Step 330 and S340. According to another embodiment, Step 330 and Step 340 may be performed before performing Step 310 and S320.

Because the feedback device 130 is used to provide a feedback path, the structure of the feedback device 130 may be simpler than that of a fan. The failure probability of the feedback device 130 may be lower, and it may be easier to debug when the feedback device is at fault. Hence, a testing process can be performed without installing a fan, thereby avoiding the trouble to check and replace a damaged fan, and eliminating the time to wait for the fan to reach a desirable speed.

In summary, by means of a fan circuit test system and a test method provided by an embodiment, a circuit related to a fan may be tested without the need to install a fan. The time required for a testing process can be reduced, and damaging the fan while testing the circuit can be avoided. The problem of the difficulty to clarify the cause of error can be reduced. In addition, a proper solution for testing a circuit board that does not have a fan pre-installed or a circuit board whose fan installed thereon does not have its type specified is provided. A Self-test related to a circuit and a controller may be performed to test a circuit related to a fan. Hence, the solution provided by embodiments is beneficial for dealing with problems in the field.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fan circuit test system, comprising:
a controller configured to output a first pulse width modulation signal and perform a test according to the first pulse width modulation signal and a first fan speed signal, and comprising:
a pulse width modulation signal terminal configured to output the first pulse width modulation signal; and
a fan speed signal terminal configured to receive the first fan speed signal;
a fan connector configured to output a second pulse width modulation signal corresponding to the first pulse width modulation signal and output the first fan speed signal corresponding to a second fan speed signal, and comprising:
a first input terminal coupled to the pulse width modulation signal terminal of the controller and configured to receive the first pulse width modulation signal;
a first output terminal configured to output the second pulse width modulation signal;
a second input terminal configured to receive the second fan speed signal; and
a second output terminal coupled to the fan speed signal terminal of the controller and configured to output the first fan speed signal; and
a feedback device configured to generate the second fan speed signal corresponding to the second pulse width modulation signal, and comprising:
a first terminal coupled to the first output terminal of the fan connector and configured to receive the second pulse width modulation signal; and
a second terminal coupled to the second input terminal of the fan connector and configured to output the second fan speed signal.

2. The fan circuit test system of claim 1 wherein the second pulse width modulation signal is identical to the second fan speed signal.

3. The fan circuit test system of claim 1 wherein the first pulse width modulation signal is identical to the second pulse width modulation signal, and the first fan speed signal is identical to the second fan speed signal.

4. The fan circuit test system of claim 1 wherein the second pulse width modulation signal is identical to the second fan speed signal.

5. The fan circuit test system of claim 1, further comprising:
a power supply comprising a first terminal configured to provide power and a second terminal coupled to a ground;
wherein the fan connector further comprises a power terminal coupled to the first terminal of the power supply and a ground terminal coupled to the second terminal of the power supply.

6. The fan circuit test system of claim 1 wherein the controller sets the first pulse width modulation signal so that the first pulse width modulation signal has a predetermined duty cycle, and the controller checks whether the first fan speed signal has the predetermined duty cycle.

7. The fan circuit test system of claim 1 wherein the controller sets the first pulse width modulation signal so that the first pulse width modulation signal has a predetermined frequency, and the controller checks whether the first fan speed signal has the predetermined frequency.

8. The fan circuit test system of claim 1 wherein the controller sets the first pulse width modulation signal so that the first pulse width modulation signal has a predetermined frequency and a predetermined duty cycle, and the controller checks whether the first fan speed signal has the predetermined frequency and the duty cycle.

9. The fan circuit test system of claim 1 wherein the feedback device comprises a jumper or a customized connector.

10. A test method used for a fan circuit test system, the fan circuit test system comprising a controller, a fan connector coupled to the controller, and a feedback device coupled to the fan connector, the test method comprising:
the controller outputting a first pulse width modulation signal to the fan connector;
the fan connector outputting a second pulse width modulation signal corresponding to the first pulse width modulation signal to the feedback device;
the feedback device outputting a second fan speed signal corresponding to the second pulse width modulation signal to the fan connector;
the fan connector outputting a first fan speed signal corresponding to the second fan speed signal to the controller; and
the controller performing a test according to the first fan speed signal and the first pulse width modulation signal.

11. The test method of claim 10 wherein the controller sets the first pulse width modulation signal so that the first pulse width modulation signal has a predetermined duty cycle, and the controller checks whether the first fan speed signal has the predetermined duty cycle.

12. The test method of claim 10 wherein the controller sets the first pulse width modulation signal so that the first pulse width modulation signal has a predetermined frequency, and the controller checks whether the first fan speed signal has the predetermined frequency.

13. The test method of claim 10 wherein the controller sets the first pulse width modulation signal so that the first pulse width modulation signal has a predetermined frequency and a predetermined duty cycle, and the controller check whether the first fan speed signal has the predetermined frequency and the predetermined duty cycle.
